(19) United States
(12) Patent Application Publication
(10) Pub. No.: US 2018/0210027 A1
(43) Pub. Date: Jul. 26, 2018

(54) SEMICONDUCTOR DEVICE TESTING

(71) Applicant: Infineon Technologies AG, Neubiberg (DE)

(72) Inventor: Andreas Kalt, Treffen (AT)

(21) Appl. No.: 15/867,266

(22) Filed: Jan. 10, 2018

(30) Foreign Application Priority Data
Jan. 20, 2017 (DE) 102017101051.3

(51) Int. Cl. G01R 31/26; H01L 21/66; G05F 1/59

(52) U.S. Cl. CPC G01R 31/2607; G01R 31/2601; G05F 1/59; H01L 22/34

(57) ABSTRACT

Methods and devices are provided. A device may comprise a main current path (11) between a terminal (10) and a supply voltage rail (15). Furthermore, an auxiliary current path (12) coupled to associated measurement circuitry to output a test measurement result (res) is provided.

This Application claims priority to German Application Number 102017101051.3, filed on Jan. 20, 2017, the entire content of which is incorporated herein by reference.

### TECHNICAL FIELD

The present application relates to devices and methods relating to the testing of semiconductor devices.

### BACKGROUND

Testing semiconductor devices is an important part of the design and manufacturing process of such devices. For safety relevant devices like automotive semiconductor devices, in particular if the devices have small feature sizes, the testing of purely functional parameters against a specification for the respective device may not always be sufficient in order to fulfil high reliability and quality requirements of customers. Therefore, for such devices additional test time is needed, covering for example design for test (DfT), design for reliability (DfR) and/or design for manufacturability (DfM) topics.

For such semiconductor devices, testing costs may be 25% or more of overall production costs and require considerable time. Furthermore, testing circuitry may cause considerable overhead, which also increases the costs.

Some conventional back-end testing approaches where a packaged device is tested like digital IDDQ testing or SCAN testing moreover require additional pins for a circuit package and external testers, which is also not desirable for cost reasons. In front end-testing, corresponding wafer-level pads are needed which are then contacted by tester needles. It should be noted that in many cases it is more desireable to detect defective devices already at the front-end processing level and at least prior to packaging and to discard the devices then, to avoid packaging costs for defective devices.

Similar considerations apply to the testing of analog parts or the testing of oxides under stress. Examples for such oxides include gate oxides, oxide of capacitors or oxide used for other isolation purposes. As a non-limiting example, gate oxide stress tests may for example performed for on-chip actuator devices.

It is therefore an object to provide devices and methods related to testing techniques which overcome or mitigate at least some of the above drawbacks of conventional approaches.

### SUMMARY

A device as defined in claim 1 and a method as defined in claim 17 are provided. The dependent claims define further embodiments.

According to an embodiment, a device is provided, comprising: a terminal,

a first current path coupled between the terminal and a supply voltage rail,

a second current path coupled to the supply voltage rail, wherein the second current path is coupled to measurement circuitry.

In some implementations, the device may be implemented in a single package and/or integrated on a single chip.

According to another embodiment, a method is provided, comprising:

using a first current path between a terminal and a supply voltage rail at least for normal operation of a device, and

using a second current path coupled to the supply voltage rail for at least one kind of test measurement.

The above summary is merely intended to give a brief overview over some features of some non-limiting embodiments and is not to be construed as limiting.

### BRIEF DESCRIPTION OF THE DRAWINGS

FIG. 1 is a block diagram of a device according to an embodiment.

FIG. 2 is a diagram illustrating a device according to an embodiment.

FIGS. 3, 4, 5A, and 5B are diagrams illustrating various testing approaches.

FIG. 6 is a circuit diagram of a device according to an embodiment.

FIG. 7 is a circuit diagram of a device according to an embodiment.

FIG. 8 is a circuit diagram of a device according to an embodiment.

FIG. 9 is a flowchart illustrating a method according to an embodiment.

### DETAILED DESCRIPTION

In the following, various embodiments will be described referring to the attached drawings. It should be noted that these embodiments are given for illustrative purposes only and are not to be construed as limiting. For example, while embodiments may be described as comprising numerous features or elements, in other embodiments some of these features or elements may be omitted, and/or may be replaced by alternative features or elements. In addition, apart from the features or elements explicitly shown in the drawings or described herein, further features or elements may be provided, for example features or elements conventionally used in testing of electronic devices.

Features or elements from different embodiments may be combined to form further embodiments. Variations or modifications described with respect to one of the embodiments may also be applied to other embodiments unless noted otherwise.

Any electrical connections shown in the drawings or described herein may be direct electrical connections or couplings, i.e. electrical connections or couplings without intervening elements, or may be indirect connections or couplings, i.e. electrical connections or couplings with one or more additional intervening elements, as long as the general purpose of the connection or coupling, for example to transmit a certain kind of signal, to transmit a certain kind of information or to provide a certain kind of control, is essentially maintained.

Embodiments may be applicable both to front-end testing, e.g. on wafers prior to dicing, and to back-end testing, e.g. to packaged chips, and are not limited to any specific stage of a manufacturing process.

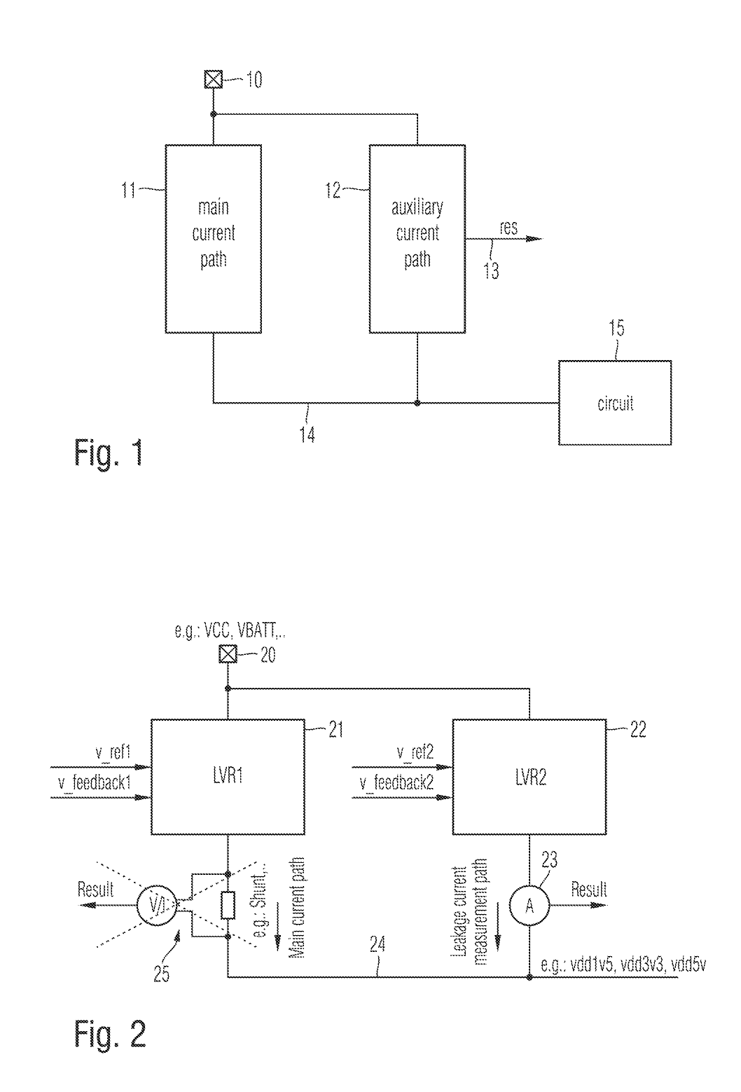

Some embodiments use an additional current path between a terminal and an internal supply voltage rail of a device for measurement. An example embodiment using such techniques is illustrated in FIG. 1. FIG. 1 illustrates a semiconductor device comprising a supply terminal 10 and a circuit 15 to be supplied via supply terminal 10. Circuit 15 may comprise any electronic circuit to perform a desired function of the device, e.g. analog and/or digital circuitry, logic circuitry, processing circuitry etc. In some embodiments, the components illustrated in FIG. 1 are provided in an integrated manner on a single semiconductor die and/or are provided within a single package. Terminal 10 may for example correspond to a pin or other contact element of a chip die or package, or may correspond to a chip internal supply voltage rail.

Terminal 10 is coupled to a supply voltage rail 14 via a main current path 11 and an auxiliary current path 12. Main current path 11 may for example comprise a first voltage regulator like a linear voltage regulator (LVR) to provide a stabilized voltage on supply rail 14 based on a supply voltage applied to terminal 10. Auxiliary current path 12 may comprise a further voltage regulator, which in some embodiments may have a simpler structure than the voltage regulator of main current path 11. Auxiliary current path 12 may furthermore comprise a measurement device like a current measurement device, also referred to as ampere meter, to measure a current flowing through auxiliary current path 12, and to provide a measurement result res via an output 13.

In some embodiments, during normal operation of the device of FIG. 1 only main current path 11 is active, and auxiliary current path 12 is deactivated. In this way, measurement elements of auxiliary current path 12 do not influence normal operation and for example do not cause any losses. On the other hand, at least for some test measurements, main current path 11 is deactivated, and auxiliary current path 12 is active. One example for such test measurements are leakage current measurements, where a voltage is applied to terminal 10 and a current through auxiliary current path 12 is measured in a deactivated state of circuit 15. In such a case, no significant current should flow, and measuring a current above a threshold may indicate a faulty device. It should be noted that main current path 11 may also be used, either alone for other tests or in conjunction with auxiliary current path 12, for example for providing voltage stress (i.e. a supply voltage above the supply voltage in normal operation). Furthermore, the example of leakage current tests is not to be construed as limiting, and auxiliary current path 12 may also be used for other kinds of tests. Furthermore, the measurement device like a current measurement device of auxiliary current path 12 may also be used for other tests which otherwise do not involve auxiliary current path 12 in some embodiments. In this way, in some embodiments circuit area may be saved. Furthermore, by providing a measurement possibility and therefore testing possibility in auxiliary current path 12, in some embodiments test time may be reduced.

FIG. 2 is a diagram of a device according to an embodiment. The embodiment of FIG. 2 may be seen as an implementation example for current paths 11 and 12 of FIG. 1, but may also be implemented independently from the embodiment of FIG. 1.

The device of FIG. 2 comprises a terminal 20, which may for example be a pin of a semiconductor package or a contact terminal on a semiconductor chip die. In operation, a supply voltage may be applied to terminal 20, for example a battery voltage VBAT or a positive supply voltage VCC or VDD.

A first linear voltage regulator (LVR) 21 is coupled between terminal 20 and a supply voltage rail 24 to generate a supply voltage, for example a supply voltage of 1.5 V, 3.3 V or of 5 V, depending on a technology used. Supply voltage rail 24 then may supply semiconductor circuits coupled to rail 24 (not shown in FIG. 2). Linear voltage regulator 21 may receive a reference voltage v_ref1 and a feedback voltage v_feedback1 derived from a voltage at supply voltage rail 24 to provide a stabilized voltage on supply voltage rail 24. Linear voltage regulator 21 may for example be used to provide the supply voltage on supply voltage rail 24 in normal operation of the device.

Furthermore, the device of FIG. 2 comprises a second linear voltage regulator 22 coupled between terminal 20 and supply voltage rail 24. A current measurement device (ampere meter) 23 is coupled between linear voltage regulator 22 and supply voltage rail 24 for current measurements, for example leakage current measurements, as will be explained further below. Linear voltage regulator 22 receives a second reference voltage v_ref2, which may be the same or different from reference voltage v_ref1 received by linear voltage regulator 21, and a second feedback voltage v_feedback2 based on a voltage on supply rail 24, which may be the same as feedback voltage v_feedback1, although this need not be the case. In some cases, the feedback voltage may be adjustable to adjust a voltage on rail 24. Linear voltage regulators 21, 22 may be implemented in the same or similar manner, but may also be implemented differently from each other. For example, linear voltage regulator 22 may be implemented in a simpler manner than linear voltage regulator 21, as linear voltage regulator 22 in some embodiments is only used for testing purposes, which may relax the requirements on linear voltage regulator 22.

In some embodiments, for a leakage current measurement linear voltage regulator 21 may be deactivated, and second linear voltage regulator 22 may be activated. A voltage may be applied to terminal 20, and a leakage current may be measured using current measurement device 23. In this way, no current measurement, as indicated by arrow 25, is necessary in a current path providing the supply voltage to supply voltage rail 24 in normal operation via linear voltage regulator 21. The main current path used also during normal operation via first linear voltage regulator 21 is not affected by the provision of the current measurement device. It should be noted that also linear voltage regulator 21 may be used for some tests. For example, in some embodiments, a test may be performed where a circuit connected to supply voltage rail 24 is stressed to higher voltages than used in normal operation, and then leakage currents may be measured. In some embodiments, the stress may be performed via first linear voltage regulator 21 by setting the reference voltage v_ref1 to higher values (second linear voltage regulator 22 may be deactivated during this stressing), and then a leakage test may be performed using second linear voltage regulator 22 (first linear voltage regulator 21 may be deactivated during this leakage measurement test).

The leakage current measurement path including linear voltage regulator 22 and current measurement device 23 may be sized to a minimum, as only low currents usually flow in such leakage measurement. Furthermore, the voltage during the leakage measurement phase is adjustable by adjusting v_ref2.

No external test pad need to be provided, and the result may for example be output on any available terminal, which may be used for other purposes during normal operation. The result of the measurement by current measurement device 23 may also be evaluated on-chip. In this case, evaluation circuitry provided may also be used for other measurements, for example test measurements on chip, for example in conjunction with other voltage regulators (for example for other supply rails).

The device of FIG. 2 may for example be used for digital IDDQ tests or any other tests where a current flowing through a circuit need to be measured, for example tests of analog circuitry.

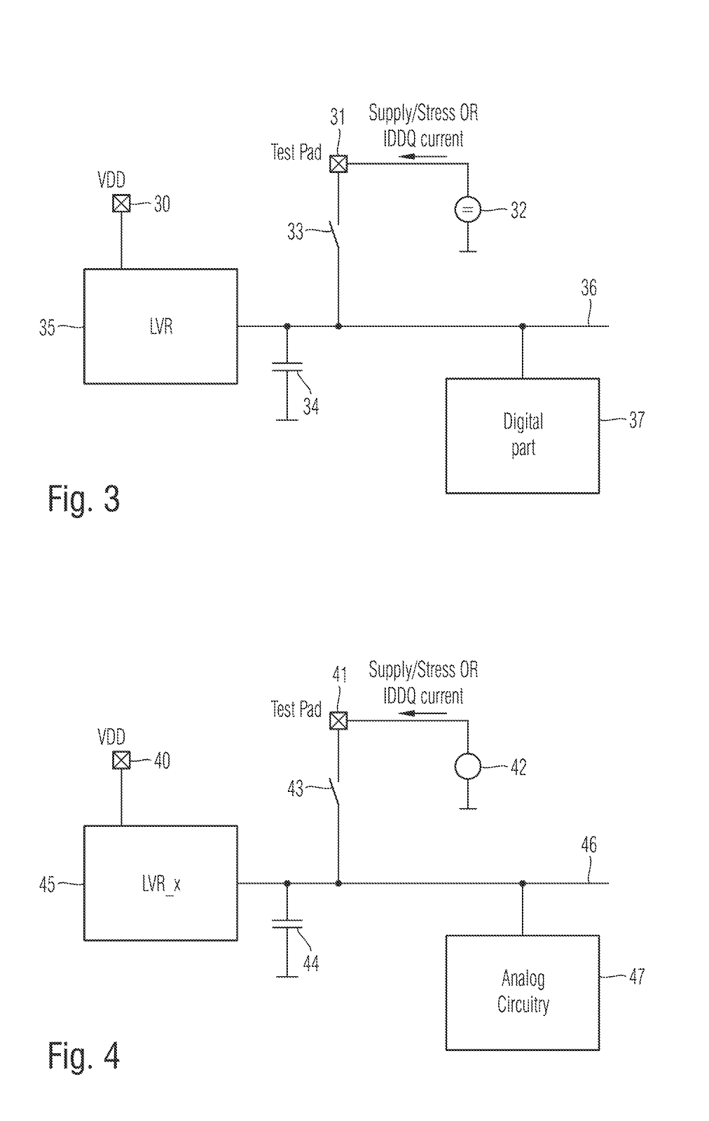

To give a better understanding of IDDQ tests and other tests which may be performed with devices of some embodiments, FIGS. 3-5 illustrate several tests which may be performed on semiconductor devices, at least some of which may be performed with embodiments described herein, for example the embodiment of FIGS. 1 and 2 or described above or the embodiments of FIGS. 6-8 described later.

FIG. 3 is a diagram illustrating testing of a digital part 37 of a circuit. In normal operation, digital part 37 is supplied from a supply voltage rail 36, which receives a stabilized voltage from a linear voltage regulator 35. Linear voltage regulator 35 is supplied via a pad 35, to which for example a positive supply voltage VDD may be applied. Numeral 34 illustrates a capacitance between supply voltage rail 36 and ground, which capacitance may serve as a buffer for peak currents.

For a SCAN testing including the measurement of an IDDQ current, in the conventional approach of FIG. 3 by a current source 32 a stress or IDDQ current/voltage is supplied to digital part 37 via a test pad 31 and a switch 33. The leakage current is then measured by a current measurement device (not shown) coupled to test pad 31. In some cases, the test pad 31 is provided as the peak current flowing during execution of a scan pattern test under increased voltage may be comparatively large and cannot be supplied via linear voltage regulator 36.

In contrast to the conventional approach of FIG. 3, in the embodiment of FIG. 2 no test pad like test pad 31 for supplying a stress or IDDQ voltage/current is needed (although it optionally may be provided), while, as explained above, still essentially the same measurements may be performed.

FIG. 4 illustrates a similar testing arrangement in a device for analog circuitry. Such tests are sometimes referred to as analog IDDQ tests. Such analog circuitry part testing is desirable at least in some circumstances as depending on the chip size and chip architecture an analog circuit part may have a significant contribution to an overall error rate of a device.

In normal operation, in the embodiment of FIG. 4 analog circuitry 47 is supplied by a supply voltage rail 46 which receives a supply voltage from a linear voltage regulator 45. Linear voltage regulator 45 is supplied via a terminal 40, for example with a positive supply voltage VDD.

Numeral 44 denotes a capacitance between supply voltage rail 46 and ground which may serve as a buffer for peak currents.

For testing, similar to the digital testing described with respect to FIG. 3, in the conventional approach of FIG. 4 a voltage stress or IDDQ current is supplied by a voltage source 42 via a dedicated test pad 41 and a switch 43. Again, in contrast to FIG. 4, in the embodiment of FIG. 2 no additional test pad is needed, and the approach shown in FIG. 2 is suitable both for analog and digital circuits.

Therefore, in contrast to the approaches in FIGS. 3 and 4, the approach of FIG. 2 may have the advantage that no test pin or pad is needed, and no additional tester resource (voltage supply 32 or 42) is needed.

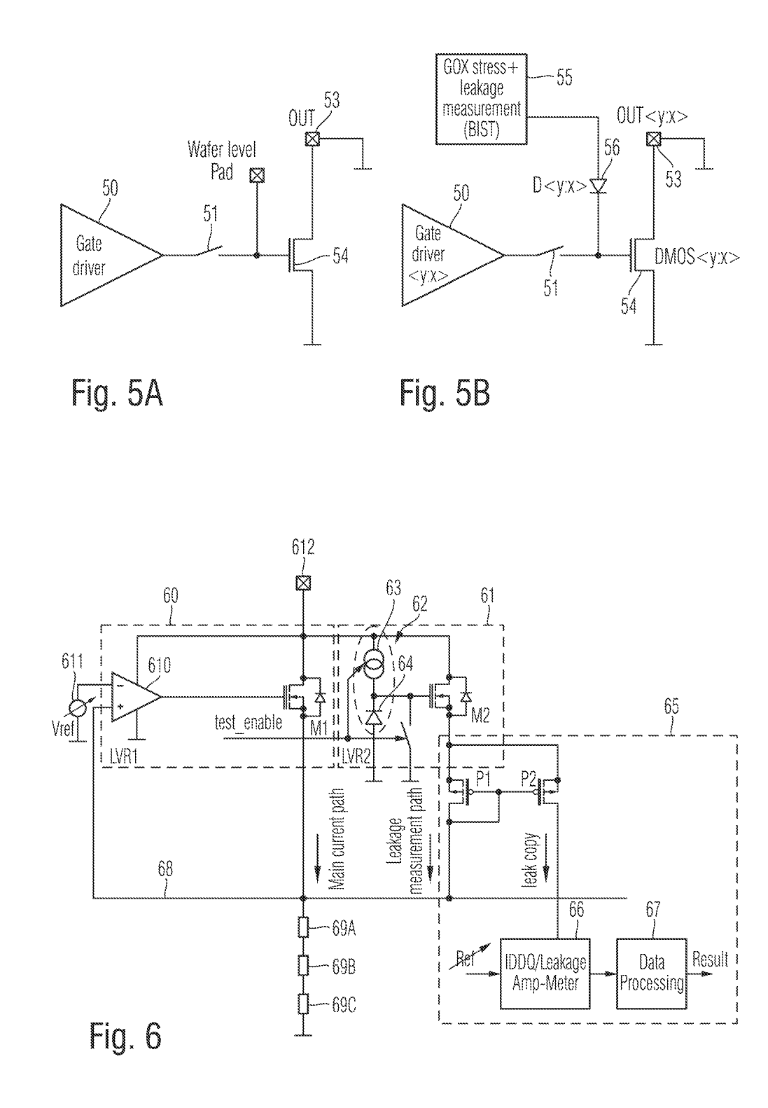

The stress generated by applying a stress voltage in FIGS. 3 and 4 may highlight possible production related defects like particles, gate oxide weaknesses etc. For on-chip actuator devices like DMOS transistors, specific gate oxide stress tests may be performed in some embodiments. The principle of such gate oxide stress tests is shown in FIGS. 5A and 5B. In order to avoid repetitions, in FIGS. 5A and 5B similar or corresponding elements bear the same reference numerals and will not be described twice.

Both in FIGS. 5A and 5B, in normal operation a switch transistor 54, for example a DMOS transistor, is controlled by a gate driver 50 via a switch 51. For test purposes, switch 51 is opened, and stress is applied to the gate of switch transistor 54.

In FIG. 5A, stress is provided via a wafer level test pad 52, and a leakage current is measured at an output pad 53 coupled to ground. In case of FIG. 5B, for providing stress and leakage measurement, a built-in self-test circuit 54 is used, which provides a stress voltage and/or leakage current via a diode 56. Built-in self-test circuitry 55 may be used for a plurality of switch transistors 54, as indicated by <y:x> in FIG. 5B.

In embodiments, a current measurement device like current measurement device 23 of FIG. 2 may also be used to measure a leakage current for such gate stress tests. In this way, no additional current measurement device for such leakage measurements needs to be provided in some embodiments. In other embodiments, separate current measurement devices may be used.

FIG. 6 illustrates a device according to a further embodiment. The embodiment of FIG. 6 comprises a first linear voltage regulator 60 and a second linear voltage regulator 61 both coupled between a supply voltage terminal 612, e.g. pin, and a supply voltage rail 68. Via supply voltage rail 68, for example a digital and/or analog part (not shown in FIG. 6) circuit may be supplied.

First linear voltage regulator 60 comprises a comparator 610 comparing a voltage on voltage rail 68 to a reference voltage Vref generated by a reference source 611, for example a bandgap reference source. An output of comparator 610 controls a transistor M1 to thus regulate the voltage on voltage rail 68. Linear voltage regulator 610 is used for example in normal operation of the device of FIG. 6.

Comparator 610 is supplied by a supply voltage provided at terminal 612.

Second linear voltage regulator 61 comprises a voltage reference 62 which in the example of FIG. 6 is formed by a current source 63 and a Zener-diode 64 to control a second transistor M2. Other voltage references may also be used. As voltage regulator 61 does not directly receive feedback from voltage rail 68, its regulation is less precise than the regulation of first voltage regulator 60. Nevertheless, for testing purposes such a comparatively simple implementation is often sufficient. A gate of transistor M2 may be coupled to ground via a signal test enable which also deactivates and activates current source 63. In this way, via signal test enable, second linear voltage regulator 61 may be activated and deactivated. Transistors M1 and M2 need not be matched. In some embodiments, transistor M2 has a minimum area sized for the leakage current (IDDQ current).

For current measurement, a current mirror formed by transistors P1 and P2 is provided in a path between second transistor M2 and supply voltage rail 68. The mirrored current is measured by an ampere meter 66 and processed by data processing circuit 67. For example, for a leakage test, data processing circuit 67 may output a warning or fault message if a current measure exceeds a predetermined threshold. Data processing circuit 67 may comprises for example logic elements, processing circuitry, filters or other elements like comparators to evaluate the measured current. In some embodiments, ampere meter 66 and data processing circuit 67 may be supplied by a different voltage supply than the circuit parts to be tested (i.e. not via supply voltage rail 68), which in some cases may reduce measurement errors.

Next, performing some tests with the embodiment shown in FIG. 6 will be discussed.

In normal operation, second linear voltage regulator 61 is deactivated by signal test enable, and first linear voltage regulator 60 provides a regulated voltage on supply voltage rail 68. For a dynamic or static stressing (i.e. with varying voltages or a constant voltage) of circuit parts coupled to supply voltage rail 68, also first voltage regulator 60 is used. A higher voltage may be generated by increasing the reference voltage generated by reference voltage generator 611 and/or by operating a resistive divider 69A-69C in FIG. 6.

For leakage current measurements, e.g. after stressing, at first, first linear voltage regulator 60 is still activated and regulates the voltage on supply voltage rail 68. The target voltage in an embodiment is set to the nominal voltage (for example 1.5 V, 3.3. V, 5 V or any other supply voltage required on supply voltage rail 68 in normal operation), and second linear voltage regulator 61 is activated by signal test enable. Via the voltage reference formed by current source 63 and diode 64, the target output voltage is selectable, for performing a current measurement at an increased voltage. The output voltage in embodiments is set high enough that first linear voltage regulator 60 gets “pinched off” by second linear voltage regulator 61. In other words, second linear voltage regulator 61 generates a voltage on supply voltage rail 68 which is so high that the output signal of comparator 610 causes transistor M1 to be in an off state, such that the complete leakage current to be measured (if a leakage current exists) flows via transistor M2. The leakage current is then measured by the measurement part 65 as explained. In order to keep the voltage on voltage rail 68 low during current measurement, the target output voltage 68 of linear voltage regulator 60 may be set to lower values in some embodiments than in normal operation.

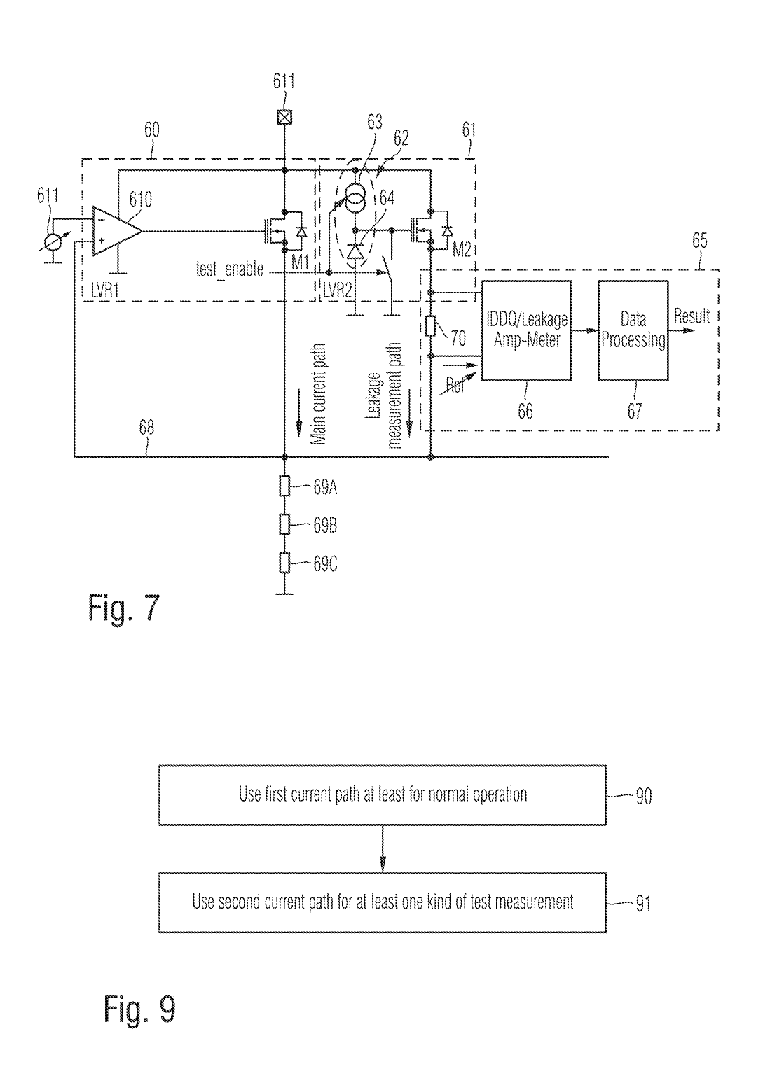

The use of a current mirror like the ones formed by transistors P1, P2 in FIG. 6 for current measurement is merely an example, and other current measurement techniques may also be used. An example is shown in FIG. 7. Apart from modifications discussed below, the embodiment of FIG. 7 corresponds to the embodiment of FIG. 6, and corresponding elements bear the same reference numerals and will not be described again in detail.

In FIG. 7, instead of the current mirror formed by transistors P1, P2, a shunt resistor 70 is provided in the current path between transistor M2 and supply voltage rail 68. A leakage current flowing leads to a voltage drop over shunt resistor 70, which is then measured by ampere meter 66. Other current measurement techniques may be used as well, for example current measurements based on magnetic field sensors, current measurements using transformers etc. Therefore, the present application is not limited to any specific current measurement techniques, as long as the leakage currents, which are usually quite small, can be measured.

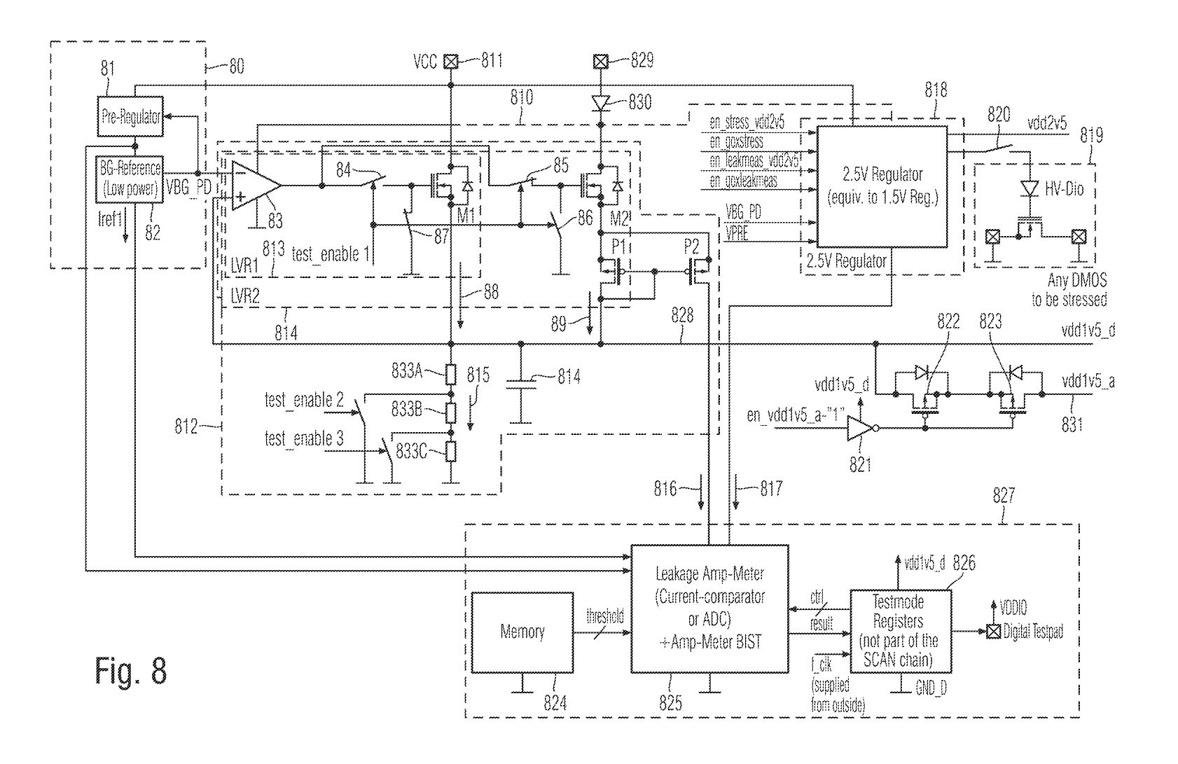

FIG. 8 illustrates a device according to a further embodiment, which has some additional testing possibilities and which also shows some additional optional features. For ease of discussion, and to avoid repetitions, when describing the embodiment of FIG. 8, sometimes reference will be made to the previously described embodiments.

The embodiment of FIG. 8 comprises a first linear voltage regulator 813 and a second linear voltage regulator 814 coupled between a supply voltage terminal 811 (for example for receiving a positive supply voltage VCC) and a supply voltage rail 828. In the embodiment of FIG. 8, first and second linear voltage regulators 813, 814 share a comparator 83. Comparator 83 compares a voltage on supply voltage rail 828 with a reference voltage generated by a standby regulator 80. Standby regulator 80 comprises a pre-regulator 81 and a bandgap reference 82 as shown and generates a reference current Iref1 for other purposes besides generating a reference voltage for comparator 83.

For first linear voltage regulator 813, comparator 83 controls a first transistor M1, and for second linear voltage regulator 814, comparator 83 controls a second transistor M2. It should be noted that such an implementation may also be used for example in the embodiments of FIG. 6 or 7, or the implementation of FIG. 6 or 7 with a separate linear voltage regulator not sharing a component like a comparator may also be used in the embodiment of FIG. 8.

A signal test_enable1 selectively enables either first linear voltage regulator 813 or second linear voltage regulator 814.

For activating first linear voltage regulator 813, switches 84 and 86 are closed, and switches 85 and 87 are open. For enabling second linear voltage regulator 814 (and disabling first linear voltage regulator 813), which corresponds to the state shown in FIG. 8, switches 84 and 86 are open and switches 85 and 87 are closed. Numeral 88 denotes a main current flowing via transistor M1, for example in normal operation, while numeral 89 denotes a leakage current.

In the example of FIG. 8, second linear voltage regulator 814 is supplied by an optional test pin 829 and a diode 830. In other embodiments, this additional pad may be omitted, and second linear voltage regulator 814 may regulate a supply voltage provided on pin 811 (using connection 810 coupling drain terminals of transistors M1 and M2), similar to what has been explained referring to FIGS. 6 and 7. The additional test pad 829 may for example also serve as a backup solution for supplying second linear voltage regulator 814 via terminal 811. This backup solution also allows operating M2 in the triode region, which simplifies the control under high load current dynamics.For example, comparator 86 serving as a gate driver may set the gate voltage of transistor M2 sufficiently high with respect to a drain voltage of transistor M2 such that transistor M2 is operated in a linear region as a switch. In other words, in such a case second linear voltage regulator 814 may be a simple switch and has an associated measurement path for providing the measurement result. It should be noted that this backup concept may also be applied to the embodiments of FIGS. 6 and 7.

In the example shown, in normal operation first linear voltage regulator 813 generates a first supply voltage on supply voltage rail 828, for example a supply voltage of 1.5 V. Second linear voltage regulator 814 is used for leakage current measurements as discussed above, and current may be measured via a current mirror formed by transistors P1, P2 feeding a leakage ampere meter 825, which may comprise a current comparator or an analog to digital converter and/or an ampere meter for built-in self-tests.

A capacitor 814 serves as a buffer capacitor for example for peak currents during testing.

In the device of FIG. 8, a further voltage regulator block 818 may be provided, which in normal operation provides a higher supply voltage than linear voltage regulator 813, for example a supply voltage of 2.5 V in contrast to a supply voltage of 1.5 V provided by linear voltage regulator 813 in normal operation. Regulator block 818 may be designed as the regulator for 1.5 V, i.e. with a first linear voltage regulator like first linear voltage regulator 813 and a second linear voltage regulator like second linear voltage regulator 814, but may also be designed differently. Therefore, also regulator block 818 may have an additional current path to measure a leakage current. Numeral 810 denotes an optional path in case an analog measurement via terminal 829 of a leakage current is not needed and no pad (wafer-level pad or package pin) is available.

It should be noted that the standby regulator block 80 may also be reused for providing a reference voltage VBG PD to regulator block 818, such that no separate voltage references need to be provided.

Leakage currents by the various regulators may be measured by common ampere meter circuitry 827 comprising a mirrored leakage current 816 from the current mirror P1, P2, a leakage current 818 (for example mirrored) in a path of regulator block may be provided to leakage ampere meter 825 for measurement, as indicated by an arrow 817. A memory 824 may store one or more thresholds, for example a same leakage current threshold for all leakage measurements or different leakage current thresholds for different leakage measurements, for example of different regulator blocks. Test mode registers 826 may be used to store results of the evaluation and measurement to be output at a digital test pad. Therefore, the embodiment of FIG. 8 provides common current measurement and evaluation circuitry 827 for various parts of the device of FIG. 8.

In the embodiment of FIG. 8, regulator 818 may further be used for gate oxide screening for example of DMOS switches 819 using current paths as discussed above. These current paths may be dedicated paths for gate oxide screening. To this effect, switches 820 may be provided via which such DMOS transistors or other transistors to be stressed like DMOS transistor 819 may be selectively coupled to regulator 818. A leakage path (e.g. comprising a second linear voltage regulator) as discussed above of regulator block 818 may then be used to measure a leakage current at the gate oxide via measurement block 827.

Further, the embodiment of FIG. 8 comprises transistors 822, 823 coupled to supply voltage rail 828 which are enabled by a driver 821 to provide the supply voltage (for example 1.5 V) on an additional supply voltage rail 831. When the path via transistors 822, 823 is disabled by driver 821, stress and leakage current measurements via this path may be performed using the techniques discussed above.

In the embodiment of FIG. 8, a resistive divider 833A-833C is coupled to supply voltage rail 828. Similar to resistive divider 69A-69C illustrated with respect to FIG. 6 resistive divider 833A-833C may be used to select a voltage on supply rail 828. As shown in FIG. 8, controlled by signals test_enable2 and test_enable3, nodes between resistors 833A-833D may be selectively coupled to ground, thus changing a voltage on supply voltage rail 828 and therefore a feedback voltage to comparator 83, which may be used to increase or lower the voltage for stress tests. For example, in some embodiments by signal test_enable3 a voltage on supply voltage rail 828 may be increased to 2.5 V (from 1.5 V in normal operation), and by signal test_enable2 to 3 V, to provide various levels of stress. Also, in other embodiments, more than two levels may be provided. It should be noted that this may also be applied to the embodiments of FIGS. 6 and 7.

It should further be noted that while the embodiment of FIG. 8 illustrates numerous details and specifics, in other embodiments only some of the details and specifics shown in FIG. 8 may be implemented. For example, in some embodiments, regulator block 818 may be omitted.

FIG. 9 illustrates a flowchart of a method according to an embodiment. The method of FIG. 9 may be used with any of the devices explained with reference to FIGS. 1-8 and for ease of illustration, will be described referring to FIGS. 1-8. However, the method of FIG. 9 may also be used independently from the embodiments discussed above. Moreover, while the method of FIG. 9 is shown and described as a series of acts or events, the order in which these acts or events are described is not to be construed as limiting.

At 90, the method comprises using a first current path for normal operation of a device, for example for supplying a supply voltage rail via a linear voltage regulator as described. Optionally, the first current path may also be used for applying a stress voltage to circuit portions, as also described.

At 91, the method comprises using a second path for at least one kind of test measurement, the second current path being essentially parallel to the first current path, for example also supplying a supply voltage rail. The test measurement may be a current measurement like a leakage current measurement/IDDQ measurement. In some embodiments, the measurements performed may also include gate oxide stress tests, as explained for example referring to FIG. 8.

From the plurality of variations and modifications described above, it is evident that the described embodiments are illustrative only and are not to construed as limiting.

1. A device, comprising:
a terminal,
a first current path coupled between the terminal and a supply voltage rail, and
a second current path coupled to the supply voltage rail, wherein the second current path is coupled to measurement circuitry.

2. The device of claim 1, wherein the measurement circuitry comprises current measurement circuitry.

3. The device of claim 1, wherein the second current path is configured to be used for leakage current measurements.

4. The device of claim 1, wherein the first current path is configured to be used to provide a supply voltage on the supply voltage rail in normal operation of the device.

5. The device of claim 1, wherein the first current path comprises a first voltage regulator, and wherein the second current path comprises a second voltage regulator.

6. The device of claim 5, wherein the first voltage regulator and the second voltage regulator have a shared part common to the first and second voltage regulators and separate parts separate for the first and second voltage regulators.

7. The device of claim 5, wherein a voltage providable by the first voltage regulator and/or the second voltage regulator is adjustable to provide voltage stress to a circuit coupled to the supply voltage rail.

8. The device of claim 1, further comprising digital and/or analog circuit parts coupled to the supply voltage rail.

9. The device of claim 1, wherein the second current path is coupled to the terminal.

10. The device of claim 1, wherein the second current path is coupled to a further terminal.

11. The device of claim 1, wherein the measurement circuity is coupled to at least one further device part to provide measurements for the further device part.

12. The device of claim 11, wherein the further device part comprises a voltage regulator block coupled to a further supply voltage rail.

13. The device of claim 1, wherein the measurement circuitry comprises evaluation circuitry configured to evaluate a measurement result and output a result.

14. The device of claim 1, wherein the first current path and/or the second current path are configured to be used for gate oxide stress measurements.

15. The device of claim 1, wherein the first current path and/or the second current path are configured to provide an adjustable supply voltage on the supply voltage rail.

16. The device of claim 1, further comprising switch circuitry configured to switch between a first test part for providing voltage stress via the supply voltage rail and a second test part for measuring a leakage current using said measurement circuitry.

17. A method, comprising:
using a first current path between a terminal and a supply voltage rail at least for normal operation of a device, and
using a second current path coupled to the supply voltage rail for at least one kind of test measurement.

18. The method of claim 17, wherein the at least one kind of test measurement comprises a leakage current measurement.

19. The method of claim 17, further comprising using the first current path or the second current path to provide voltage stress.

20. The method of claim 17, wherein the method is performed by measurement circuity on a device, the device comprising:
the terminal,
the first current path coupled between the terminal and a supply voltage rail, and
the second current path coupled to the supply voltage rail, wherein the second current path is coupled to the measurement circuitry.
